(19) United States
(12) Patent Application Publication
(10) Pub. No.: US 2014/0255831 A1
(43) Pub. Date: Sep. 11, 2014

(54) METHOD AND APPARATUS FOR PROTECTING A SUBSTRATE DURING PROCESSING BY A PARTICLE BEAM

(71) Applicant: Carl Zeiss SMS GmbH, Jena (DE)

(72) Inventors: Thorsten Hofmann, Rodgau (DE); Tristan Bret, Darmstadt (DE); Petra Spies, Mainz (DE); Nicole Auth, Gustavsburg (DE); Michael Budach, Hanau (DE); Dajana Cujas, Seeheim-Jugenheim (DE)

(21) Appl. No.: 14/200,264

(22) Filed: Mar. 7, 2014

Related U.S. Application Data
(60) Provisional application No. 61/774,799, filed on Mar. 8, 2013.

(30) Foreign Application Priority Data
Mar. 8, 2013 (DE) 102013203995.6

(51) Int. Cl. G03F 1/72

(52) U.S. Cl. CPC G03F 1/72
USPC 430/5; 156/345.3; 118/721

(57) ABSTRACT

The invention refers to a method and apparatus for protecting a substrate during a processing by at least one particle beam. The method comprises the following steps: (a) applying a locally restrict limited protection layer on the substrate; (b) etching the substrate and/or a layer arranged on the substrate by use of the at least one particle beam and at least one gas; and/or (c) depositing material onto the substrate by use of the at least one particle beam and at least one precursor gas; and (d) removing the locally limited protection layer from the substrate.

### CROSS-REFERENCE TO RELATED APPLICATIONS

This application claims priority to U.S. provisional application 61/774,799, filed on Mar. 8, 2013, and German patent application 10 2013 203 995.6, filed on Mar. 8, 2013. The contents of the above-referenced applications are incorporated by reference in their entirety.

### TECHNICAL FIELD

The present disclosure relates to a method and apparatus for protecting a substrate during a processing by a particle beam.

### BACKGROUND

As a result of the constantly increasing integration density in the semi-conductor industry (Moore's law) photolithographic masks have to image smaller and smaller structures on wafers. More and more complex processing procedures are required in order to generate this small structure dimensions on the wafer. The processing procedures have in particular to ensure that the non-processed semiconducting material is not unintentionally changed and/or modified in an uncontrolled manner by the processing procedures.

Photolithographic systems take into account the trend towards increasing integration density by shifting the exposure wavelength of lithography apparatus to smaller and smaller wavelengths. Photolithography systems presently often use an argon fluoride excimer laser as a light source which emits at a wavelength of approximately 193 nm.

At the moment, lithography systems are developed which use electromagnetic radiation in the extreme ultra violet (EUV) wavelength range (in the range of 10 nm to 15 nm). These EUV lithography systems are based on a completely new concept for beam guiding which exclusively uses reflective optical elements, since there are presently no materials available which are optically transparent in the indicated EUV range. The technological challenges for the development of EUV systems are enormous, and huge development efforts are necessary in order to bring these systems to industrial operability.

It is therefore mandatory to further develop conventional lithography systems in order to thereby increase the integration density in the near future.

Photolithographic masks or exposure masks play a significant role when imaging smaller and smaller structures in a photoresist arranged on a wafer. With each further enhancement of the integration density, it becomes more and more important to improve the minimum structure size of exposure masks.

The application of molybdenum doped silicon nitride or silicon oxynitride layers as absorber material on a substrate of a photolithographic mask is one possibility to meet these challenges. Molybdenum doped silicon nitride or molybdenum doped silicon oxynitride are in the following called MoSi layers.

The application of a MoSi layer for defining the structure elements to be imaged into the photoresist allows adjusting that a certain portion of the electromagnetic radiation incident on the MoSi layer can penetrate this layer. The molybdenum content essentially determines the absorption of the MoSi layer. The phase difference of the radiation penetrating the transparent mask substrate is adjusted to 180° or π by an etching process of the mask substrate and/or by a corresponding layer thickness of the MoSi layer. Thus, a MoSi absorber layer allows imaging structures with a larger contrast in the photoresist than binary exposure masks can do. Therefore, smaller and more complex structures can be represented on a mask substrate compared with conventional binary absorber layers on the basis of metals. Hence, a MoSi absorber layer accomplishes a significant contribution to the improvement of the resolution of an exposure mask.

The generation of errors cannot be excluded during a mask fabrication process due to the tiny structure sizes of the absorber elements and the extreme requirements for exposure masks. The manufacturing process of photolithographic masks is highly complex and very time consuming and thus expensive. Therefore, exposure masks are repaired whenever possible.

Typically, an ion beam induced (FIB) sputtering or an electron beam induced etching (EBIE) are used for a local material removal of excessive material of conventional absorber layers of exposure masks on the basis of metals, as for example chromium or titanium. For example, these processes are described in the article of T. Liang et al: “Progress in extreme ultra violet mask repair using a focused ion beam”, J. Vac. Sci. Technol. B.18 (6), 3216 (2000) and in the patent EP 1 664 924 B1 of the applicant.

With the progressively decrease of the structure elements of photolithographic masks further aspects of the absorber structure elements of photolithographic masks are gaining attention which have up to now not been important. For example, the durability of the absorber layer and the durability of the absorber layers in a chemical cleaning process and/or under radiation with ultraviolet radiation become more and more important. The molybdenum content of the MoSi layer has a decisive influence on these properties. It is a general rule that the lower the molybdenum content is the more resistive the layers are with respect to their durability regarding chemical cleaning and UV radiation. Therefore, it is desirable to also decrease the molybdenum content of MoSi layers when decreasing the structural elements of the absorber layer.

On the other hand, the molybdenum content has significant effects for the repair of mask defects which have been generated during the manufacturing process. The local removal of excessive MoSi absorber material by using an electron beam and the presently usual etching gases becomes more and more difficult with decreasing molybdenum content of the MoSi layer. In the following, this is illustrated for an electron beam induced etching process using xenon difluoride (XeF₂) as an etching gas.

FIG. 1 shows a segment of a substrate of a mask from which a rectangular MoSi layer has been etched down to the substrate during several minutes. The MoSi layer has a molybdenum content in the one digit percentage range as it is presently usual. The etching process only causes a moderate surface roughness of the substrate (dark area) of the photolithographic mask in the area of the removed MoSi layer. The area of the mask substrate outside of the etching process does not show a significant modification.

FIG. 2 shows the segment of the substrate of the mask of FIG. 1 after etching a MoSi layer having a molybdenum content which is only half of that of FIG. 1. The etching process for removing the MoSi layer with the lower molybdenum content needs a multiple of the time for the MoSi layer of FIG. 1. The etching process which needs a long time generates an increased roughness of the substrate around the MoSi layer. This can be recognized from the bright halo around the ground area of the MoSi layer. Moreover, the etching process causes significant damages of the mask substrate in the region of the ground area of the MoSi layer which are recognizable by the dark spots in this area. The further utilization of the exposure masks is questionable due to the substrate damages caused by the etching process.

Apart from the molybdenum content of the MoSi layer, the etching behavior significantly depends on the nitrogen content of the MoSi material system. A larger nitrogen content of the MoSi layer significantly complicates the removal of excessive MoSi material.

The present invention is therefore based on the problem to indicate methods and an apparatus for protecting a substrate during processing the substrate and/or a layer arranged on the substrate by using a particle beam which at least partially avoid the drawbacks and restrictions mentioned above.

### SUMMARY

According to an aspect of the present invention, in an embodiment, the method for protecting a substrate during a processing by at least one particle beam comprises the following steps: (a) arranging a locally limited protection layer on the substrate; (b) etching the substrate and/or a layer arranged on the substrate by using the at least one particle beam and at least one gas; and/or (c) depositing material onto the substrate by the at least one particle beam and at least one precursor gas; and (d) removing the local limited protection layer from the substrate.

The known problem of riverbedding often occurs in particle beam induced processing procedures, i.e., material is unintentionally removed in the area around the etching process or sputtering process. Apart from the particle beam, the extent of the occurring riverbedding depends on the gas(es) used in the etching process.

Arranging a protection layer around the material to be removed from the MoSi layer prevents that the etching process can locally damage the mask substrate independent from its duration and independent from the used etching gas. Hence, the roughening of the surface of the substrate illustrated in FIG. 2 can reliably be avoided. Furthermore, the protection layer also avoids the above mentioned riverbedding or the local deposition of material on the substrate during a processing procedure.

In an aspect, arranging the locally limited protection layer comprises: arranging the protection layer adjacent to a portion of the substrate or to the layer which is to be processed and/or arranging the protection layer in a distance from the layer within which material is to be deposited onto the substrate.

According to a further aspect, arranging the protection layer further comprises: depositing a protection layer which has an etch selectivity compared to the substrate of larger than 1:1, preferred larger than 2:1, more preferred larger than 3:1, and most preferred larger than 5:1.

In a further aspect, arranging the protection layer further comprises depositing a layer by use of an electron beam and at least one volatile metal composition on the substrate.

Preferably, the volatile metal composition comprises at least one metal carbonyl precursor gas and the at least one metal carbonyl precursor gas further comprises at least one of the following compounds: molybdenum hexacarbonyl (Mo(CO)₆), chromium hexacarbonyl (Cr(CO)₆), vanadium hexacarbonyl (V(CO)₆), tungsten hexacarbonyl (W(CO)₆), nickel tetracarbonyl (Ni(CO)₄), iron pentacarbonyl (Fe₃(CO)₅), ruthenium pentacarbonyl (Ru(CO)₅), and osmium pentacarbonyl (Os(CO)₅).

Also preferred, the at least one volatile metal composition comprises a metal fluoride, and the metal fluoride further comprises at least one of the following compounds: tungsten hexafluoride (WF₆), molybdenum hexafloride (MoF₆), vanadium fluoride (VF₂, VF₃, VF₄, VF₅), and/or chromium fluoride (CrF₂, CrF₃, CrF₄, CrF₅).

In another aspect, the locally limited protection layer comprises a thickness of 0.2 nm-1000 nm, preferred 0.5 nm -500 nm, and most preferred 1 nm-100 nm, and/or has a lateral extension on the substrate of 0.1 nm-5000 nm, preferred 0.1 nm -2000 nm, and most preferred 0.1 nm-500 nm.

In the context of this application a locally limited protection layer means a protection layer whose lateral extensions are adapted to the size of a processing location. A processing location is a defect on the substrate and/or a defect on a layer arranged on the substrate having excessive or missing material. In addition to the size of the processing location, the lateral extensions of a protection layer also depend on the applied particle beam, its parameters as well as the gas(es) used for the processing.

According to a further aspect, depositing material comprises depositing material on the substrate adjacent to the layer arranged on the substrate.

In still a further aspect, the at least one gas comprises at least one etching gas. Preferably, the at least one etching gas comprises xenon difluoride (XeF₂), sulfur hexafluoride (SF₆), sulfur tetrafluoride (SF₄), nitrogen trifluoride (NF₃), phosphor trifluoride (PF₃), nitrogen oxygen fluoride (NOF), molybdenum hexafluoride (MoF₆), hydrogen fluoride (HF), triphosphor trinitrogen hexafluoride (P₃N₃F₆), or a combination of these gases.

According to a beneficial aspect, removing the protection layer comprises directing an electron beam and at least one second etching gas to the protection layer, wherein the at least second etching gas has an etch selectivity compared to the substrate of larger than 1:1, preferred larger than 2:1, more preferred larger than 3:1, and most preferred larger than 5:1.

In a further aspect, removing the protection layer comprises directing the electron beam and at least one second etching gas to the protection layer, wherein the at least one second etching gas comprises a chlorine containing gas, a bromine containing gas, an iodine containing gas and/or a gas which comprises a combination of these halogens. Preferably, the at least one second etching gas comprises at least a chlorine containing gas.

In a further especially preferred aspect, removing the protection layer of the substrate is effected by means of a wet chemical cleaning of the substrate.

According to another aspect, the substrate comprises a substrate of a photolithographic mask and/or the layer arranged on the substrate comprises an absorber layer. The absorber layer preferably comprises MoₓSiO_{y}N_{z}, wherein 0≦x≦0.5, 0≦y≦2, and 0≦z≦4/3.

The material system MoₓSiO_{y}N_{z} comprises four different compounds as limiting cases:

(a) molybdenum silicide for y=z=0;

(b) silicon nitride or silicon nitrogen layer systems for x=y=0;

(c) molybdenum-doped silicon oxide for z=0; and

(d) molybdenum-doped silicon nitride for y=0.

According to a further embodiment of the present invention, the method for removing portions of an absorber layer, which are arranged on portions of a surface of a substrate of a photolithographic mask, wherein the absorber layer comprises MoₓSiO_{y}N_{z} and wherein 0≦x≦0.5, 0≦y≦2 and 0≦z≦4/3, comprises the step: directing at least one particle beam and at least one gas on the at least one portion of the absorber layer to be removed, wherein the at least one gas comprises at least one etching gas and at least one second gas, or wherein the at least one gas comprises the at least one etching gas and at least one second gas in one compound.

In the above described alternative of a removal process of excessive MoSi absorber material, the occurrence of damages of the mask substrate is prevented in that the etching process is accelerated by the addition of a second gas, or the etching process on the substrate material is slowed down. Alternatively, both etching rates can be slowed down, wherein, however, the etching rate on the substrate is significantly stronger slowed down than the etching rate of the MoSi material, so that in total the effect of the secondary particles on the substrate is limited. The second gas or its composition can be adjusted to the material composition of the respective MoSi layer.

A further beneficial aspect comprises changing a ratio of gas flow rates of the at least one etching gas and the at least one second gas during a time period when the at least one particle beam and the at least one gas are directed on the at least one portion of the absorber layer to be removed. Preferably, the composition of the at least one second gas is changed prior to reaching a layer boundary between the absorber layer and the substrate.

In another aspect, the at least one second gas comprises a gas which provides ammonia. Preferably, the at least one ammonia providing gas comprises ammonia (NH₃), ammonium hydroxide (NH₄OH), ammonium carbonate ((NH₄)₂CO₃), diimine (N₂H₂), hydrazine (N₂H₄), hydrogen nitride (HNO₃), ammonium hydrogen carbonate (NH₄HCO₃) and/or diammonia carbonate ((NH₃)₂CO₃).

According to a further aspect, the at least one etching gas and the at least one ammonia providing gas is provided in one compound and the compound comprises trifluoro acetamide (CF₂CONH₂), triethylamine trihydro fluoride ((C₂H₅)₃N.₃HF), ammonium fluoro ride (NH₄F), ammonium difluoride (NH₄F₂) and/or tetrammine copper sulfate (CuSO₄.(NH₃)₄).

According to another aspect, the at least one second gas comprises at least water vapor.

In a beneficial aspect, the at least one second gas comprises an ammonia providing gas and water vapor.

According to a beneficial aspect, the at least one second gas comprises at least one metal precursor gas, and the at least one metal precursor gas comprises one of the following compounds: molybdenum hexacarbonyl (Mo(CO)₆), chromium hexacarbonyl (Cr(CO)₆), vanadium hexacarbonyl (V(CO)₆), tungsten hexacarbonyl (W(CO)₆), nickel tetracarbonyl (Ni(CO)₄), iron pentacarbonyl (Fe₃(CO)₅), ruthenium pentacarbonyl (Ru(CO)₅) and/or osmium pentacarbonyl (Os(CO)₅).

In a beneficial aspect, the at least one second gas comprises at least one metal carbonyl and water vapor, and/or at least an ammonia providing gas.

According to a preferred aspect, the at least one second gas comprises oxygen, nitrogen and/or at least one nitrogen oxygen compound. According to a further aspect, the at least one second gas comprises oxygen, nitrogen and/or at least one nitrogen oxygen compound and an ammonia providing gas. According to a further aspect, the at least one second gas comprises oxygen, nitrogen, and/or at least one nitrogen oxygen compound and water vapor.

In still another aspect, directing the at least one second gas onto the portion of the absorber layer to be removed comprises activating the oxygen, the nitrogen and/or the at least one nitrogen oxygen compound with an activating source.

Nitrogen oxide (NO) radicals can lead to an amplification of the oxidation of silicon nitride at the surface. Thereby, the etching rate of fluorine-based reagents can significantly be accelerated (cf. Kastenmeier et. al.: “Chemical dry etching of silicon nitride and silicon dioxide using CF₄/O₂/N₂ gas mixtures”, J. Vac. Sci. Technol. A (14(5), p. 2802-2813, September/August 1996).

According to a beneficial aspect, a method for protecting a substrate during a processing by use of at least one particle beam comprises the following steps: (a) arranging a locally limited protection layer on the substrate; (b) etching the substrate and/or a layer arranged on the substrate by use of the at least one particle beam and at least one gas; and/or (c) depositing material onto the substrate by use of the at least one particle beam and at least one precursor gas; and (d) removing the locally limited protection layer from the substrate. Further, the method comprises performing at least one step according to one of the above indicated aspects.

The combination of arranging a locally limited protection layer and the application of a gas which comprises an etching gas and a second gas, on the one hand, enables by the adjustment of two independent parameters to protect the mask substrate surrounding a defect, and, on the other hand, enables to protect the area of the substrate below the defect from damages by the processing procedure of the absorber layer. The second gas allows thereby the optimization of the etching process without having to fear damages of the substrate. Thus, the second gas can exclusively be selected for optimizing the etching process, and for avoiding substrate damages below the defect without any tradeoff.

In a further aspect, the substrate of the photolithographic mask comprises a material which is transparent in the ultraviolet wavelength range and/or the particle beam comprises an electron beam. In addition to an electron beam, an ion beam is also beneficial. In this process, ions beams are preferred which are generated by means of a gas field ion source (GFIS), and a noble gas, such as helium (He), neon (Ne), argon (Ar), krypton (Kr) and/or xenon (Xe).

The application of the above defined method is not restricted to a substrate of a photolithographic mask. Rather, the method allows reliably protecting all semiconductor materials during a processing step and/or during a correction of local defects. Moreover, a locally limited protection layer can generally be used for protecting any materials, such as an isolator, a semiconductor, a metal, or a metal compound during a particle beam induced local processing procedure of the material. Finally, the above discussed method can also be used for removing defects of reflective masks for the extreme ultraviolet (EUV) wavelength range.

A further aspect of the present invention refers to an apparatus for protecting a substrate during a processing by means of at least one particle beam, wherein the apparatus comprises: (a) means for arranging a locally limited protection layer on the substrate; (b) means for etching the substrate and/or a layer arranged on the substrate by means of the at least one particle beam and at least one gas; and/or (c) means for depositing material on the substrate by means of the at least one particle beam and at least one precursor gas; and (d) means for removing the locally limited protection layer from the substrate.

According to another aspect, the apparatus is configured to execute a method according to any one of the above indicated aspects.

According to a further aspect, the apparatus comprises further means for generating a second particle beam for activating oxygen, nitrogen and/or a nitrogen oxygen compound.

### DESCRIPTION OF THE DRAWINGS

In the following detailed description presently preferred application examples of the invention are described with respect to the drawings, wherein

FIG. 1 shows a segment of a top view of a substrate of a mask from which a MoSi layer has been removed, wherein the molybdenum content of the MoSi layer was in a one digit percent range;

FIG. 2 represents a segment of a top view of a substrate of an exposure mask from which the MoSi layer has been etched off, wherein the molybdenum content of the MoSi was approximately half of that of FIG. 1;

FIG. 3 depicts a cross section through schematic representation of an apparatus for correcting absorber defects of photolithographic masks;

FIG. 4 shows a schematic top view of a segment of a line-space structure made from absorber material in which one line or stripe has a defect at which excessive absorber material has been deposited;

FIG. 5 schematically represents the arrangement of a local limy ited protection layer for the defect of FIG. 4;

FIG. 6 schematically represents the etching of the defect of FIG. 5 by use of an electron beam and an etching gas;

FIG. 7 schematically illustrates etching of the defect of FIG. 5 by use of an electron beam, an etching gas and an ammonia providing gas;

FIG. 8 represents a segment of a mask from which a rectangular MoSi layer having a low molybdenum content has been removed by use of an electron beam, XeF₂ as an etching gas, and ammonium hydroxide (NH₄OH);

FIG. 9 schematically illustrates etching the defect of FIG. 5 by use of an electron beam, an etching gas, an ammonia providing gas, and water vapor;

FIG. 10 schematically represents etching the defect of FIG. 5 by use of an electron beam, an etching gas, an ammonia providing gas and nitrogen monoxide radicals;

FIG. 11 schematically reproduces etching the defect of FIG. 5 by the use of an electron beam, an etching gas, a metal carbonyl, an ammonia providing gas, and/or water;

FIG. 12 shows FIGS. 7 and 9-11 after finalization of the removal of the defect of FIG. 5;

FIG. 13 schematically represents an etching process for removing the locally limited protection layer of FIG. 12;

FIG. 14 schematically depicts the section of the mask of FIG. 13 after removing the protection layer;

FIG. 15 shows a schematic top view of a segment of a line-space structure made from absorbing material, at which a line or stripe has a defect of missing absorber material;

FIG. 16 represents a cross section through a schematic representation of a photolithographic mask during the process of arranging a locally limited protection layer;

FIG. 17 shows a cross section through the mask of FIG. 16 during a deposition process of missing absorber material;

FIG. 18 represents the cross section through the mask of FIG. 17 during removing the locally limited protection layer; and

FIG. 19 indicates a cross section through the mask of FIG. 18 after the removal of the locally limited protection layer.

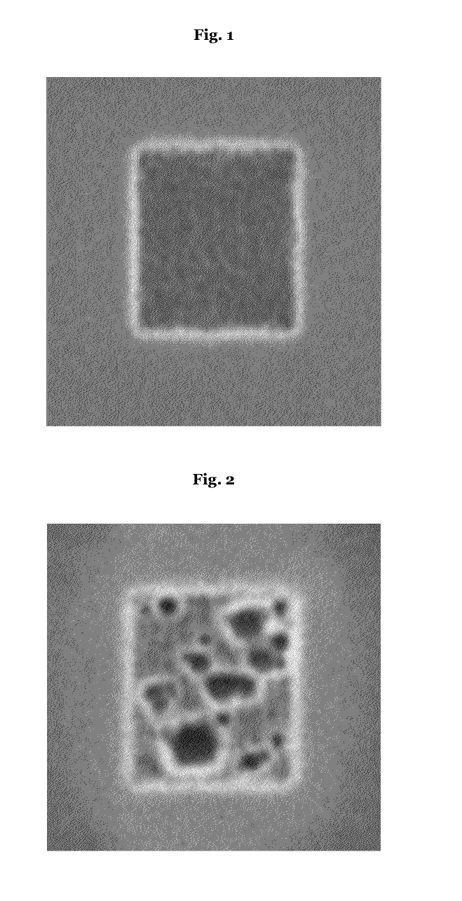

### DETAILED DESCRIPTION

In the following preferred embodiments of the inventive method and the inventive apparatus are described in more detail. These are explained using the example of processing defects of photolithographic masks. However, the inventive method and the inventive apparatus are not limited to the application of photolithographic masks. Rather, they can be utilized for processing semiconductor materials during the manufacturing process and/or during a repair process. It is also possible to use a locally limited protection layer for protecting arbitrary materials during a local processing by the use of a particle beam.

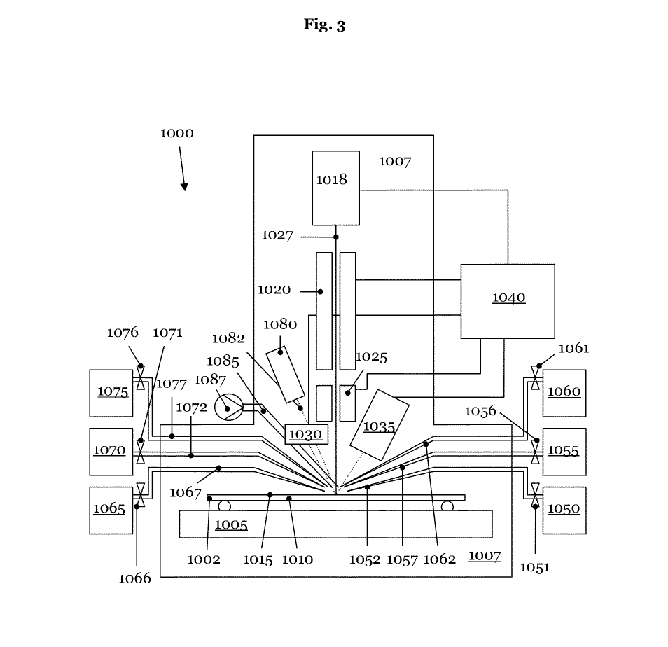

FIG. 3 shows a cross section of a schematic representation of preferred components of an apparatus 1000 which can be used for repairing local defects of an absorber structure of a mask, and which can at the same time prevent a substrate of the mask from damages during a repairing process. The exemplary apparatus woo of FIG. 3 is a modified scanning electron microscope (SEM). An electron gun 1018 generates an electron beam 1027 and the beam forming and beam imaging elements 1020 and 1025 direct the focused electron beam 1027 either on the substrate 1010 of an exposure mask 1002, or to an element of the absorber structure arranged on the surface 1015 (not shown in FIG. 3).

The substrate 1010 of the mask 1002 is arranged on the sample stage 1005. The sample stage 1005 comprises an offset slide—which is not represented in FIG. 3—which allows that the mask 1002 can be shifted in a plane perpendicular to the electron beam 1027 so that the defect of the absorber structure of the mask 1002 is below the electron beam 1027. The sample stage 1005 can further include one or several elements by the use of which the temperature of the substrate 1010 of the mask 1002 can be set to a predetermined temperature and can be controlled at a predetermined temperature (not indicated in FIG. 3).

The exemplary apparatus 1000 of FIG. 3 uses an electron beam 1027 as a particle beam. The electron beam 1027 can be focused on a small spot with a diameter of less than 10 nanometers on the surface 1015 of the mask 1002. The energy of the electrons impinging on the surface 1015 of the substrate 1010 or onto an element of the absorber structure can be varied across a large energy range (from a few eV up to 50 keV). When impinging on the surface 1015 of the substrate 1010, the electrons do not cause significant damages of the substrate surface 1015 due to their small mass.

The usage of the method defined in this application is not limited to the usage of an electron beam 1027. Rather, any particle beam can be used which is capable to induce a local chemical reaction of a precursor gas at the position at which the particle beam hits the mask 1002 and where a corresponding gas is provided. Examples of alternative particle beams are ion beams, metal beams, molecular beams and/or photon beams.

It is also possible to use two or more particle beams in parallel. A laser system 1080 is incorporated in the apparatus 1000 exemplarily represented in FIG. 3 which generates a laser beam 1082. Thus, the apparatus 1000 allows simultaneously applying an electron beam 1027 in combination with a photon beam 1082 to the mask 1002. Both beams 1027 and 1082 can continuously be provided or in the form of pulses. Moreover, the pulses of the two beams 1027 and 1082 can simultaneously partially overlap or can intermediary react on the reaction site. The reaction site is the position at which an electron beam 1027 induces alone or in combination with the laser beam 1082 a local chemical reaction of a precursor gas.

Additionally, the electron beam 1027 can be used for scanning across the surface 1015 for recording an image of the surface 1015 of the substrate 1010 of the mask 1002. A detector 1030 for backscattered and/or secondary electrons which are generated by the electrons of the incident electron beam 1027 and/or by the laser beam 1082 provides a signal which is proportional to the composition of the substrate material 1110, or to the composition of the material of the elements of the absorber structure. Defects of the absorber structure elements of the mask 1002 can be determined from the image of the surface 1015 of the substrate 1010. Alternatively, defects of the absorber structure of a mask 1002 can be determined by exposing a wafer and/or by the use of the recording of one or several air images for example determined by means of an AIMS™.

A computer system 1040 can determine an image of the surface 1015 of the substrate 1010 of the mask 1002 on the basis of a signal of the detector 1030 obtained from a scan of the electron beam 1027 and/or the laser beam 1082. The computer system 1040 can include algorithms realized in hardware and/or software which allow determining an image of the surface 1015 of the substrate 1010 of the mask 1002 from the data signal of the detector 1030. A monitor connected with the computer system 1040 can represent the calculated image (not shown in FIG. 3). The computer system 1040 can also indicate the signal data of the detector 1030 and/or can store the calculated image (also not indicated in FIG. 3). The computer system 1040 can also control and regulate the electron gun 1018 and the beam forming and beam imaging elements 1020 and 1025 as well as the laser system 1080. Moreover, the computer system 1040 can also control the movement of the sample stage 1005 (not illustrated in FIG. 3).

The electron beam 1027 incident on the surface 1015 of the substrate 1010 of the mask 1002 can charge the substrate surface 1015. In order to reduce the effect of the charge accumulation by the electron beam 1027, an ion gun 1030 can be used for irradiating the substrate surface 1015 with ions having low energy. For example, an argon ion beam having kinetic energy of some hundreds of volts can be used for neutralizing the substrate surface 1015. The computer system 1040 can also control the ion beam source 1035.

A positive charge distribution can accumulate on the isolating surface 1015 of the substrate 1010 if a focused ion beam is used instead of an electron beam 1027. In this case, an electron beam can be used for irradiating the substrate surface 1015 in order to reduce the positive charge distribution on the substrate surface 1015.

The exemplary apparatus 1000 of FIG. 3 preferably comprises six different storage containers for different gases or precursor gases for processing one or several defects of the absorber structure arranged on the surface 1015 of the substrate 1010. The first storage container 1050 stores a first precursor gas or a deposition gas which is used in combination with the electron beam 1027 for generating a protection layer around the defect of an absorber element. The second storage container 1055 includes a chlorine containing etching gas by the use of which the protection layer is removed from the surface 1015 of the substrate 1010 of the mask 1002 after the finalization of the repairing processes for the absorber defect.

The third storage container 1060 stores an etching gas, for example xenon difluoride (XeF₂) which is used for locally removing excessive absorber material. The fourth storage container 1065 stockpiles a precursor gas for locally depositing missing absorber material on the surface 1015 of the substrate 1010 of the exposure mask 1002. The fifth 1070 and the sixth storage container 1075 contain two further different gases which can be mixed to the etching gas stored in the third storage container 1060 as needed. Moreover, the apparatus 1000 allows installing further storage containers and gas supplies as needed.

Each storage container has its own valve 1051, 1056, 1061, 1066, 1071, 1076 in order to control the amount of gas particles provided per time unit or the gas flow rate at the place where the electron beam 1027 impinges onto the substrate 1010 of the mask 1002. Additionally, each storage container 1050, 1055, 1060, 1065, 1070, 1075 has its own gas supply 1052, 1057, 1062, 1067, 1072, 1077, which ends with a nozzle close to the point of impact of the electron beam 1027 on the substrate 1010. The distance between the point of impact of the electron beam 1027 on the substrate 1010 of the mask 1002 and the nozzles of the gas supplies 1052, 1057, 1062, 1067, 1072, 1077 is in the range of some millimeters. However, the apparatus 1000 of FIG. 3 also allows the arrangement of gas supplies whose distances to the point of impact of the electron beam 1027 is smaller than one millimeter.

In the example presented in FIG. 3 the valves 1051, 1056, 1061, 1066, 1071, 1076 are implemented close to the storage container. In an alternative embodiment all or some of the valves 1051, 1056, 1061, 1066, 1071, 1076 can be arranged close to the respective nozzle (not shown in FIG. 3). Moreover, the gases of two or more storage containers can be provided by means of a common gas supply; this is also not illustrated in FIG. 3.

Each of the storage containers can have its own element for an individual temperature setup and control. The temperature setting allows both a cooling and a heating of each gas. Additionally, each of the gas supplies 1052, 1057, 1062, 1067, 1072, 1077 can also have an individual element for setting and controlling the supply temperature of each gas at the reaction site (also not indicated in FIG. 3).

The apparatus 1000 of FIG. 3 has a pumping system in order to generate and to maintain the required vacuum. Prior to starting a processing procedure, the pressure in the vacuum chamber 1007 is typically in the range of 10⁻⁵ Pa to 2·10⁻⁴ Pa. At the reaction site, the local pressure can typically increase up to a range of approximately 10 Pa.

The suction device 1085, schematically represented in FIG. 3, is an important part of the gas supply system. The suction device 1085 in combination with the pump 1087 enables that the fragments, which are generated by the decomposition of a precursor gas or parts of the precursor gas which are not needed for the local chemical reaction—as for example carbon monoxide, which originates from the electron beam induced decomposition of metal carbonyls—are essentially extracted at the place of the generation from the vacuum chamber 1007 of the apparatus 1000. A contamination of the vacuum chamber 1007 is avoided since gas components which are not needed are locally extracted from the vacuum chamber 1007 at the position of the incidence of the electron beam 1027 and/or the laser beam 1082 on the substrate 1010 before they are distributed and before they are deposited.

Preferably, an electron beam 1027 is exclusively used for initializing the etching reaction in the exemplary apparatus 1000 of FIG. 3. The accelerating voltage of the electrons is in a range of 0.01 keV to 50 keV. The current of the applied electron beam varies in an interval between 1 pA and 1 nA. The laser system 1080 provides an additional and/or alternative energy transfer mechanism by the use of the laser beam 1082. The energy transfer mechanism can for example selectively activate the precursor gas or can selectively activate components or fragments generated by the decomposition of the precursor gas in order to efficiently support local repairing processes of the absorber structure elements.

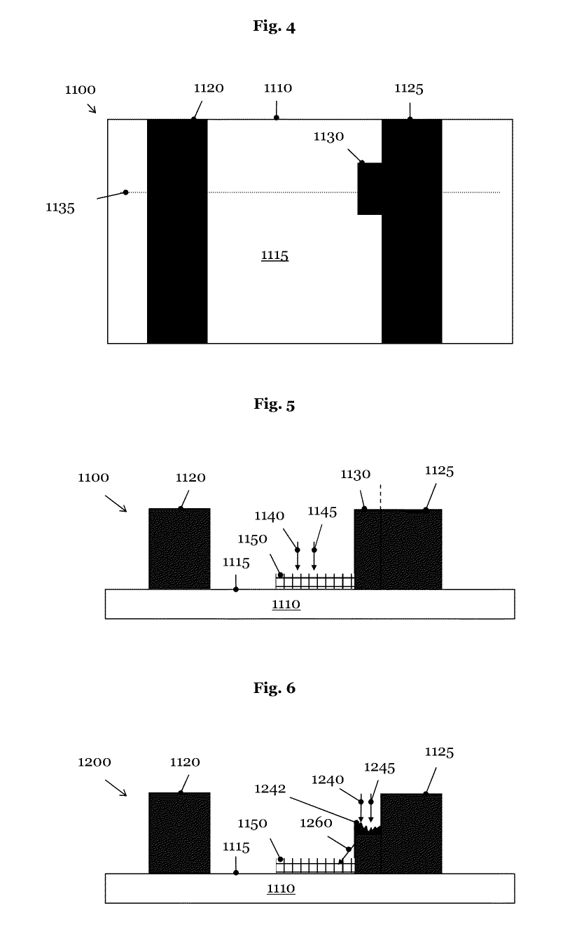

FIG. 4 schematically shows a segment of a substrate 1110 of an exposure mask 1100. A line-space structure of absorber material 1120, 1125 is arranged on a surface 1115 of the substrate 1110. The right line or stripe 1125 comprises an extension defect 1130 having excessive absorber material. The dotted line 1135 shows the cutting line of the cut or the cross-section through the segment of the exposure mask 1100 of FIG. 4, wherein the cross section is represented in FIG. 5.

The defect 1130 represented in the example of FIG. 5 has accidentally the same height as the absorber element 1125. However, this is no requirement for repairing extension defects of the absorber structure 1120, 1125 of the mask 1100. Rather, the repairing process described in the following can correct defects which are lower or higher than the absorber structure elements 1120, 1125.

In a first step, a protection layer 1150 is deposited on the surface 1115 of the substrate 1100 around the defect 1130. For this purpose, an electron beam 1140 is focused on the surface 1115 of the substrate 1110 of the mask 1100. The electron beam 1140 is scanned across the portion of the surface 1150 onto which the locally limited protection layer 1150 is to be deposited. A precursor gas is locally provided in parallel with the electron beam 1140. In principle, any deposition precursor gas can be used. Volatile metal compounds are preferred since thereby locally limited protection layers 1150 can be deposited which can easily and residue-free be removed from the substrate after the processing procedure. Metal carbonyls are beneficial from the multitude of volatile metal compounds.

A protection layer 1150 should simultaneously fulfill three essential requirements: it should be possible to apply the protection layer 1150 in a defined form on the mask substrate 1110 without significant complexity of the instruments. The protection layer 115o has to essentially resist the processing procedure of the MoSi absorber layer. Finally, it should be possible to again essentially residue-free remove the protection layer 1150 from the substrate 1110 of an exposure mask 1100. The expression essentially means here as well as on other passages of the description a change of the mask which does not compromise the functionality of the mask.

As it is already indicated above, metal carbonyls 1145 are especially well suited for depositing a protection layer 1150. Best results could up to now be reached with the metal carbonyl precursor gas molybdenum hexacarbonyl (Mo(CO)₆). Other metal carbonyls have also successfully been used, as for example chromium hexacarbonyl (Cr(CO)₆).

The energy-transferring action of the electron beam 1140 splits the carbon monoxide (CO) ligands from the central metal atom at the position of the chemical reaction, i.e., at the position at which the electron beam 1140 impinges on the surface of the substrate. The suction device 1085 removes a portion of the CO molecules from the reaction site. The metal atom of a precursor gas molecule deposits a deposit at the reaction site on the surface 1115 of the substrate 1110 of the mask 1100, as the case may be with one or more CO molecules, and thus forms the protection layer 1150.

The parameters of the electron beam 1140 during the deposition process depend from the used precursor gas. For example, for the precursor gas molybdenum hexacarbonyl (Mo(CO)₆) good results are obtained by using electrons having a kinetic energy in the range of 0.2 keV to 5.0 keV and having a beam current between 0.5 pA and 100 pA. There are no specific requirements to the focus of the electron beam for depositing the protection layer.

Molybdenum hexacarbonyl is conveyed to the reaction site through the gas supply 1052 with a gas flow rate of 0.01 sccm to 5 sccm (standard cubic centimeter per minute) which is adjusted and controlled by the valve 1058. Alternatively, the amount of gas provided at the reaction site can be controlled and regulated by the temperature of Mo(CO)₆ or more generally of metal carbonyls, and thus can be controlled or regulated by the pressure.

In addition to the material used for the protection layer 1150 the thickness of the protection layer 1150 to be deposited also depends from the subsequent processing procedure against which the protection layer 1150 has to protect the surface 1115 of the substrate 1110. The protection layer 1150, for example a Mo(CO)₆ layer, should have a thickness between 1 nm and 5 nm in order to provide protection against a processing of the defect 1130 by means of an electron beam in a subsequent removing or etching process.

The requirements to the protection layer are lower when depositing absorber material. In this case, it is sufficient that the deposited protection layer is free from pinholes so that a layer thickness of approx. 1 nm is sufficient.

The size and the form of the protection layer 1150 can be derived from the process conditions of the subsequent processing procedure. The protection layer 1150 can be produced by scanning the electron beam 1140 across the determined surface 1115 of the substrate 1110 when the metal carbonyl precursor gas 1145 is simultaneously provided.

The protection layer 1150 can comprise two or several layers. The lowest layer which is in contact with the surface 1115 of the substrate 1110 can provide a defined adhesion to the substrate 1110.

The second or the further higher layers of the locally limited protection layer 1150 can provide a defined resistance against to the subsequent adjacent processing procedure. Alternatively, the composition of the protection layer 1150 can be changed across its thickness or depth. For this purpose, in addition to the metal carbonyl precursor gas from the storage container, a second precursor gas can locally be supplied at the reaction site, for example by the sixth storage container 1175.

FIG. 6 illustrates an exemplary removal process 1200 of excessive materials of the defect 1130 by means of an electron beam 1240 and an etching gas 1245. In the example of FIG. 6, the elements of the absorber structure 1120, 1125 as well as the defect 1130 consist of MoₓSiO_{y}N_{z}, with: 0≦x≦0.5, 0≦y≦2.0, 0≦z≦4/3; this material system is in the following abbreviated with MoSi. The application of an electron beam 1240 is beneficial in that one particle beam can be used for forming the protection layer 1150 and for removing excessive MoSi material.

For example, xenon difluoride (XeF₂) can be used as an etching gas 1245. Further examples of possible etching gases are sulfur hexafluoride (SF₆), sulfur tetrafluoride (SF₄), nitrogen trifluoride (NF₃), phosphor trifluoride (PF₃), tungsten hexafluoride (WF₆), hydrogen fluoride (HF), nitrogen oxygen fluoride (NOF), triphosphor trinitrogen hexafluoride (P₃N₃F₆), or a combination of these etching gases. It is also possible to extend the etching chemicals to other halogens, as for example chlorine (Cl₂), bromine (Br₂), iodine (I₂) or their compounds, as for example iodine chlorine (ICI) or chlorine hydrogen (HCl).

An electron beam induced etching process is difficult for MoSi layers having a low molybdenum content. A very low etching rate is achieved with the above indicated etching gases 1245 and an electron beam 1240 if the MoSi material additionally has a high content of nitrogen. The secondary electrons 1260 act on the protection layer 1150 during a long time period, and can thus damage the protection layer 1150.

Etch selectivity is an important parameter characterizing an etching process. The etch selectivity is defined by the ratio of the etching rate of a first material, in general the material to be etched, to the etching rate of a second material, usually the material which is not to be etched. The larger this ratio is the more selective the etching process is, and the simpler it is to reproducibly achieve the required etching results. Applied to the etching process of FIG. 6 this means that an etch selectivity would be high if the etching process would etch the material of the MoSi layer 1130 with a much higher etching rate than the substrate 1110 of the mask 1100.

The combination of electron beam 1250 and etching gas 1245 would then remove the defect 1130 with a large rate, and the process would considerably be slowed down when reaching the layer boundary to the surface 1115 of the substrate 1110, or ideally the process would come to a standstill.

In the example of FIG. 6, the etch selectivity is in the range 1:7. This means that the electron beam 1240 and the etching gas 1245 etch the substrate 1110 of the mask 1100 much faster than the MoSi material of the defect 1130. At least two consequences arise from this result. Without the protection layer 1150 already the contribution of the forward scattered electrons 1260 would lead to a damage of the substrate 1110 of the mask 1100 which is in the same order of magnitude as the thickness of the absorber layer to be removed. The protection layer 1150 efficiently prevents this etching process.

The etching gases, which are presently used as a standard for removing MoSi material, create a kind of crater landscape on the etched surface of the defect in the course of a time consuming etching process. This is indicated in FIG. 6 by the numeral 1242. When reaching the layer boundary between the defect 1130 and the underlying substrate either a portion of the defect 1130 is not removed, if the etching process is stopped as soon as the deepest crater of the defect has reached the substrate surface 1115, or the etching process forms an amplified crater landscape in the mask substrate 1150, if the etching process is only ended after the complete removal of the defect 1130.

FIG. 2 shows the result of the etching process of FIG. 6 for a rectangular MoSi layer having low molybdenum content. The etching process 1200 of FIG. 6 has transformed the roughness 1242 of the defect 1130 into the mask substrate 1110 below the MoSi layer.

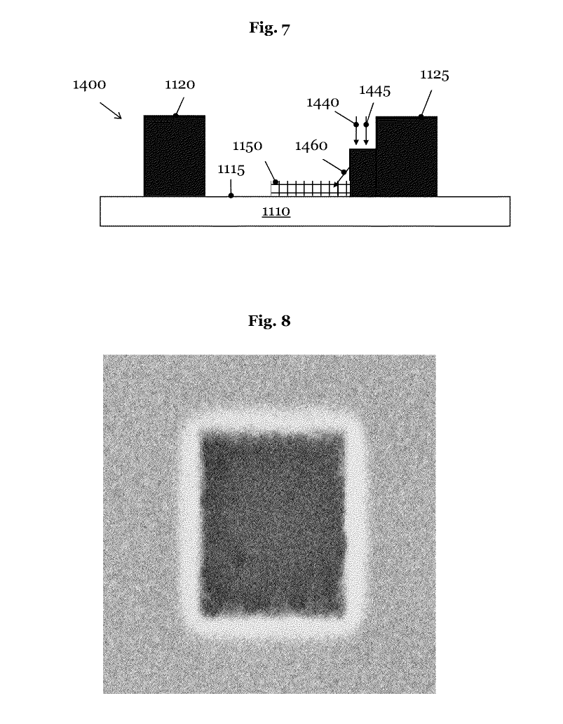

By the addition of ammonia providing gases when etching MoSi layers, the crater landscape or the roughness 1242 can significantly be reduced. FIG. 7 illustrates this fact. An ammonia providing gas or a combination of different ammonia providing gases can for example be provided by the fifth or sixth storage container 1070 and/or 1075 by means of the gas supplies 1072, 1077 at the reaction site, and can be controlled by means of their valves 1071 and/or 1076.

In addition to ammonia (NH₃), ammonium hydroxide (NH₄OH) and/or aromatic salt ((NH₄)₂CO₃) can also be used as ammonia providing gases as well as similar substances, as for example ammonium carbonate ((NH₃)₂CO₃), ammonium hydrogen carbonate (NH₄HCO₃), diimine (N₂H₂), hydrazine (N₂H₄), hydrogen carbonate (HNO₃). On the one hand, these gases slightly accelerate etching of MoSi material of the defect 1130 and, on the other hand, slow down the etching process of the substrate 1110 of the mask 1100. The slow-down is approximately a factor of 2 and the acceleration reaches approximately 40% for typical process parameters of the etching process depicted in FIG. 7. Thus, the etch selectivity in total improves from approximately 1:7 in the etching process 1200 of FIG. 6 to now 1:2.5. However, thereby the etch selectivity is still in the inverse regime. This means, the electron beam 1440 and the combination of the precursor gases 1445 still etch the substrate 1110 faster than the MoSi material of the defect 1130.

Due to the smooth etching behavior of the defect 1130, which is depicted in FIG. 7, a combination of the gases 1445 comprising an etching gas 1245 (XeF₂ in the example of FIG. 6) and at least one ammonia providing gas in combination with the detection of back scattered and/or secondary electrons as discussed in the context of FIG. 3 lead to the removal of the exemplary defect 1130 within a predetermined specification.

The ratio of the gas flow rates of the etching gas 1245 and the ammonia providing gas can be varied during the etching process 1400. A composition of the MoSi material which changes along the depth of the defect 1130 can thus be taken into account. On the other hand, the etching rate of the defect 1130 and the roughness of the substrate surface 1150 can thus be optimized in the region of the defect 1130 to be removed.

FIG. 8 shows the effect of the addition of an ammonia providing gas for the removal of a MoSi layer having low molybdenum content. In the etching process, whose result is represented in FIG. 8, ammonium hydroxide (NH₄OH) has been admixed to the etching gas XeF₂. The energy of the electron beam 1440 was in a range between 0.1 keV and 5.0 keV in the exemplary correction process of FIG. 8. The gas flow rates of XeF₂ and NH₄OH have been in the range of 0.05 sccm up to 1 sccm and from 0.01 sccm to 1 sccm, respectively.

In a modified process control, the gases 1445, i.e., the etching gas 1245 and the ammonia providing gas are provided in one chemical compound, i.e., within one gas molecule at the reaction site. For this purpose, for example the compounds trifluorine acetamide (CF₂CONH₂), triethylamine trihydrofluoride ((C₂H₅)₃N.₃HF), ammonium fluoride (NH₄F), ammonium difluoride (NH₄F₂) and/or tetrammine copper sulfate (CuSO₄.(NH₃)₄) can be used. The storage is facilitated by the application of a precursor gas which simultaneously provides an etching gas and an ammonia providing gas. Moreover, the gas supply and control is also facilitated, since only one single gas is needed instead of a mixture of several gases.

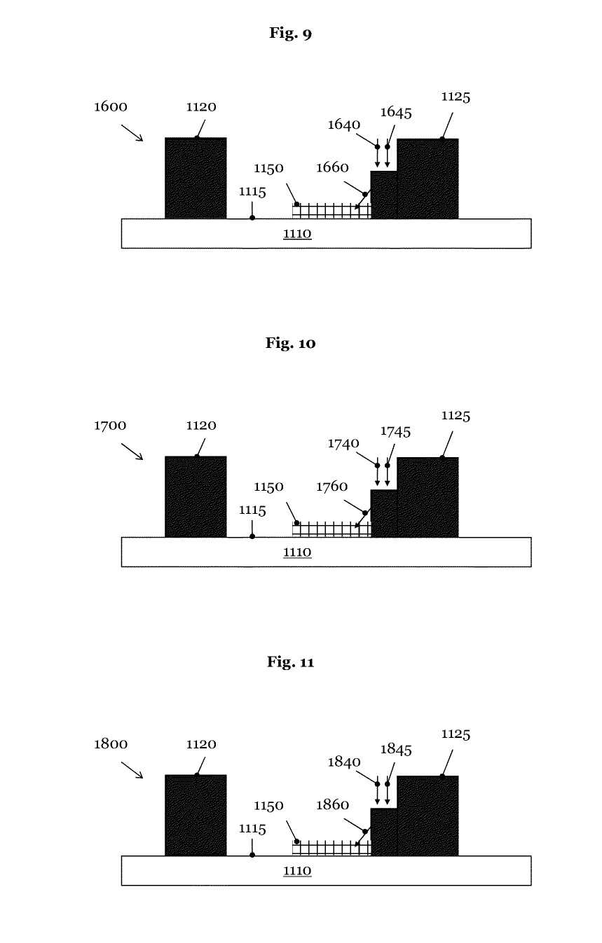

The etch selectivity can be increased in the etching process 1400 depicted in FIG. 7 if water or water vapor is additionally supplied to the reaction site in addition to the etching gas 1245 and an ammonia providing gas. FIG. 9 illustrates the etching process 1600 which is achieved in this way. On the one hand, the addition of water to the mixture of gases 1645 leads to a sharper edge of the MoSi absorber element 1125 along the defect 1130 to be removed. On the other hand, water vapor significantly improves the etch selectivity from approximately 1:2.5 (the etching process 1300 of FIG. 7) to about 1.7:i. Hence, the etching process, represented in FIG. 9, leaves the inverse regime. The increase of the etch selectivity is achieved by means of a slow-down of the etching rate. The etching rate of the MoSi layer of defect 1130 reduces by approximately a to factor of two, whereas the etching rate of the mask substrate 1155 is slowed down by approximately an order of magnitude with respect to the etching process 1400 of FIG. 7.

Thus, the etching process 1600 of FIG. 9, whose second gas 1645 comprises a combination of three substances (etching gas 1245, an ammonia providing gas and water), at least in principle can do without the protection layer 1150. However, it is beneficial not to go without the protection layer 1150 in the etching process 1600 of FIG. 9 due to the distinct affinity of ammonia supported processes to riverbedding, in particular if the MoSi material of the defect 1130 has a low molybdenum concentration and/or has a high fraction of nitrogen.

In a further variation of the etching process of FIG. 7, nitrogen monoxide (NO) is admixed to the etching gas 1245 instead of water. The etching process 1700 represented in FIG. 11 uses as a second gas 1745 a mixture of the components: etching gas 1245 and NO. The NO radicals are activated at the reaction site by the use of the electron beam 1740 and/or by means of the laser beam 1082.

As already explained in the third part of the description, NO radicals significantly increase the etching rate of silicon nitride without attacking the silicon oxygen connections of the quartz substrate 1110 of the mask 1100. Thus, the selectivity of the etching process 1700 of FIG. 10 is again increased compared with the etching process 1600 of FIG. 9. As a consequence, the etching process 1700 of FIG. 11 does in principle not need the protection layer 1150.

In a modified etching process, an ammonia providing gas is additionally added to the mixture of gases 1745 in addition to the etching gas 1245 and nitrogen monoxide. The NO radicals can again be activated as described in the previous section. Details of the composition of the MoSi material to be removed determine whether the modified etching process can be performed without the protection layer 1150.

In a further modified processing procedure of the etching process 1700 of FIG. 10, nitrogen (N₂) and oxygen (O₂) are provided at the reaction site instead of nitrogen monoxide. Nitrogen and oxygen are again activated at the reaction site by means of the electron beam 1740 and/or by the use of the laser beam 1082 of the laser system 1080 so that nitrogen and oxygen preferably react to NO. The further sequence of the etching process then takes place as described in the previous section.

As it has already been explained in the context of FIG. 2, the etching rate of a MoSi layer decreases with a decreasing fraction of molybdenum, and thus the selectivity of the etching process drastically decreases compared to the substrate 1110. The lack of metal atoms during an etching process can be balanced by adding a metal carbonyl as a precursor gas. FIG. 11 represents an etching process 1800 in which the mixture of gases 1845 has a metal carbonyl in addition to an etching gas (XeF₂ in the present case).

When using the metal carbonyls chromium hexacarbonyl (Cr(CO)₆) and molybdenum hexacarbonyl (Mo(CO)₆) extremely good results could be achieved, i.e., a significant acceleration of the etching rate of the defect 1130, and thus an increase of the etch selectivity. The application of other metal carbonyls is however also possible. Furthermore, a combination of two or more metal carbonyls can be used in the mixture of gases 1845. Generally, the etching rate can be increased by increasing the gas flow rate of the metal carbonyl(s). However, in this process it has to be taken into account that metal carbonyls are deposition gases. This means that the etching rate starts slowing down when a certain gas flow rate of the metal carbonyl(s) is exceeded, since the deposition portion starts outbalancing the portion of the enhancement of the etching rate.

The ratio of the gas flow rates of the etching gas and the metal carbonyl(s) can be adjusted to the composition of the MoSi material of the defect during the etching process in order to optimize the etching rate. The current composition of the etched material can be determined from the energy distribution of the back scattered and/or the secondary electrons of the detector 1030 of the apparatus woo of FIG. 3.

However, the acceleration of the etching rate by the addition of one or several metal carbonyl(s) to the etching gas mixture 1845 does not lead to a decrease of the roughness 1242 of the etched surface. The roughness of the etched surface can drastically be reduced by the addition of water or water vapor and/or by an ammonia providing gas.

As explained above, the reduction of the roughness is accompanied by a slowing down of the etching process. Thus, the ratios of the gas flow rates of the etching gas and the metal carbonyl, on the one hand, and of the etching gas and water and/or an ammonia providing gas, on the other hand, have to be optimized as a function of the composition of the MoSi material of the defect 1130. In an extreme case, the etching process stops if the ratio of the gas flow rates has the wrong size. The deposition effect of the metal carbonyl outweighs the etching effect of the etching gas if the gas flow rates of the metal carbonyl(s) and water and the ammonia providing gas are too high relative to the gas flow rate of the etching gas.

It is also possible to provide an etching gas and a metal atom in a single gaseous compound similarly, as it has been discussed in the context of the supply of an etching gas and a second gas in a single compound. Exemplary compositions for this process are: molybdenum hexafluoride (MoF₆), chromium tetrafluoride (CrF₄) and tungsten hexafluoride (WF₆). Moreover, further metal fluoride compounds can be used for this purpose. Finally, it is also possible to use other metal halogen compounds in order to provide further etching chemicals on the basis of further halogens apart from a fluorine-based etching chemical.

The combination of an etching gas and a metal atom in a single compound has the beneficial aspect to simplify the apparatus 1000 of FIG. 3 with respect to the storage of the respective precursor gases. Moreover, the combination in a single compound enables a more simple process control.

In a modified process control for increasing the metal content during an etching process of a MoSi layer having a low fraction of molybdenum, the metal carbonyl(s) are not added to the mixture of gases during the etching process. Rather, a thin metal layer made from one or several metal carbonyls is deposited prior to the real etching process. The metal layer provides the metal atoms which lack in the MoSi material during the etching process.

The addition of metal carbonyls to a mixture of gases also increases the etching rate of the quartz substrate 1110. Therefore, the good localization of the metal atoms during the etching process is an important advantage of the deposition of a thin metal layer on the defect 1130 so that a trade-off with respect to the etch selectivity can be avoided. For this reason, when using this process control, one can do without the protection function of the protection layer.

On the other hand, it is detrimental when using this process control that the local provision of metal atoms from the metal storage of the thin layer decreases in the course of the etching process of the defect 1130, and thus the etching rate also decreases. This disadvantage can be compensated by executing the process in several steps, i.e., by periodically depositing a thin metal layer.

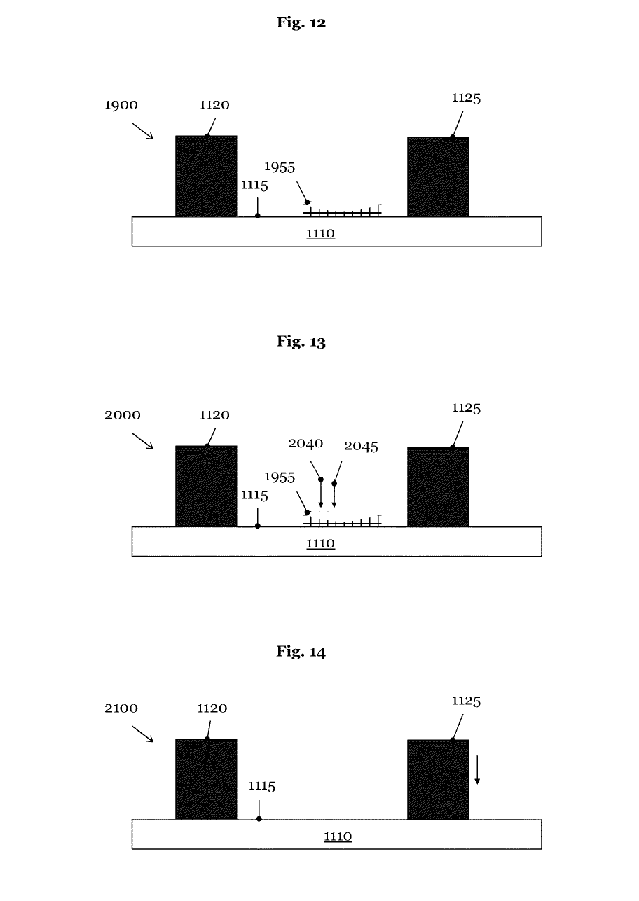

After finalization of the etching processes 1400, 1600, 1700, or 1800 represented in FIG. 7, 9, 10, or 11 a cross-section 1900 through the mask 1100 has a protection layer 1955. When compared to the protection layer 1150, the protection layer 1955 can have damages due to the effect of secondary particles 1460, 1660, 1760, or 1860 and/or the mixtures of the etching gas and the second gas 1445, 1645, 1745, or 1845. FIG. 12 schematically illustrates this by the partially removed protection layer 1955. On the other hand, the defect has been removed by one of the etching processes 1400, 1600, 1700, 1800 from the mask 1100, wherein the surface 1150 of the substrate 1110 has essentially not be roughened at the position of the defect.

FIG. 13 schematically shows the removal of a protection layer 1955 of FIG. 13 remaining after the finalization of one of the etching processes 1400, 1600, 1700, 1800. The protection layer 1150, 1955 is removed from the surface 1115 of the substrate 1110 by the use of an etching process by using an electron beam 2040 and an etching gas 2045. Generally, for removing the protection layer 1150, 1955, etching processes are beneficial which have a high selectivity with respect to the substrate 1110. In this sense, fluorine-based etching gases are not desirable. Etching gases on the bases of the remaining halogens, i.e., chlorine-, bromine- and/or iodine-based etching gases have proved successful for removing the protection layer 1150, 1955. Nitrosyl chlorine (NOCl) is used as an etching gas 2045 in the etching process of FIG. 13. The protection layer 1955 can be selectively removed from the substrate 1110 of the mask 1100 by means of NOCl, wherein the protection layer has been deposited from a metal carbonyl.

The protection layer 1150, 1955 deposited from one or several metal carbonyls has additionally the beneficial characteristic that it can residue-free be removed from the surface 1115 of the substrate 1110 with usual mask cleaning processes. Thus, the etching process 2000 illustrated in FIG. 13 is not needed. The protection layer 1150, 1955 is simply removed in the course of one of the necessary mask cleaning steps.

FIG. 14 represents a segment 2100 of the mask 1100 after finalizing the removal of the protection layer 1150, 1955. The described repairing process has removed the defect of excessive MoSi material without essentially damaging the surface 1115 of the substrate 1110.

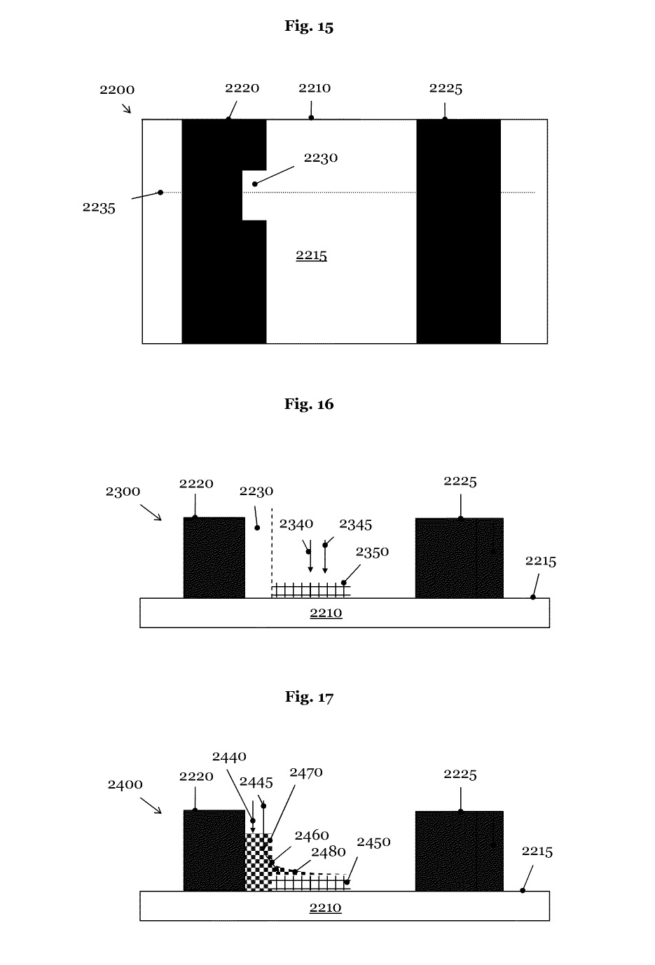

FIG. 15 schematically shows a segment of a substrate 2210 of a photolithographic mask 2200. A line-space structure 2220, 2225 made from MoSi absorber material is applied to the surface 2215 of the substrate 2210. The left line or stripe 2220 has a defect of missing absorber material. The dotted line 2235 represents the cutting line of the cross section through the segment of the exposure mask 2200 of FIG. 15, which is illustrated in FIG. 16. Prior to the repairing of the defect 2230, a protection layer 2150 is deposited on the surface 2215 of the substrate 2210 of the mask 2200 as it is schematically illustrated in FIG. 16. The protection layer 2350 is deposited by the use of an electron beam 2340 and one or more metal carbonyls or other volatile metal compounds as a precursor gas 2345. In addition to metal carbonyls, for example also wolfram fluoride (WF₆), molybdenum fluoride (MoF₆), or further metal fluoride compounds can be used.

Details for depositing a protection layer 2350 have already been explained when discussing of FIG. 5. It is the peculiarity of the protection layer 2350 compared with the protection layer 1150 of FIG. 5 that the protection layer is not arranged adjacent to the absorber element 2220 in the area of the cross section, but is arranged a distance apart from the absorber element 2220 which corresponds to the ground area of the defect 2230.

FIG. 17 schematically represents a deposition process 2400 for correcting the defect 2230. The deposition of the absorber material which lacks due to the defect 2230 takes place by providing one or several metal carbonyls 2445 at the position of the defect or at the processing position or at the reaction site as well as by means of an electron beam induced local chemical reaction of the metal carbonyl(s) 2445 by the use of the electron beam 2440. The electron beam 2440 splits the metal carbonyl(s) 2445. A portion of the separated CO ligands, or more general of the non-metallic components, are pumped down from the reaction site by the suction device 1085. The central metal atom of the metal carbonyl or the metal atom of the metal fluorine compound is deposited on the ground area of the defect 2230 together with further fragments. Thus, a layer 2470 of absorbing material is formed by repeated scans of the electron beam 2240 across the ground area of the defect 2230.

The electron beam 2240 generates secondary electrons, or more generally secondary particles 2460, similar to the etching processes of FIGS. 6, 7 and 9-11. A portion of these secondary particles will impinge on the protection layer 2350 and can split the metal carbonyl particles which are available on the protection layer, and can deposit a thin layer 2480 on the protection layer 2350 made from metal atoms and further fragments.

Chromium hexacarbonyl (Cr(CO₆)) is a preferred metal carbonyl for repairing the defect 2230. A layer of absorbing material can also be grown by other metal carbonyls or by the use of volatile metal compounds, for example by the above mentioned metal fluorine compounds. In contrasts to the protection layer 2350, the absorber layer 2470 should adhere on the surface 2250 of the substrate 2210 of the mask 2200 in the possible way, in order that the protection layer 2350 is neither damaged by cleaning processes nor by the exposure with ultraviolet radiation, and that it is not detached from the substrate 2210.

The kinetic energy of the incident electrons is in the range of 0.1 keV to 5.0 keV during the deposition process depicted in FIG. 17. Beneficial beam currents comprise a range from 0.5 pA to 100 pA. The gas flow rate of the metal carbonyl(s) extends across a range from 0.01 sccm to 5 sccm. The repetition time as well as the dwell time has to be selected in a suitable manner so that the etching rate is optimized.

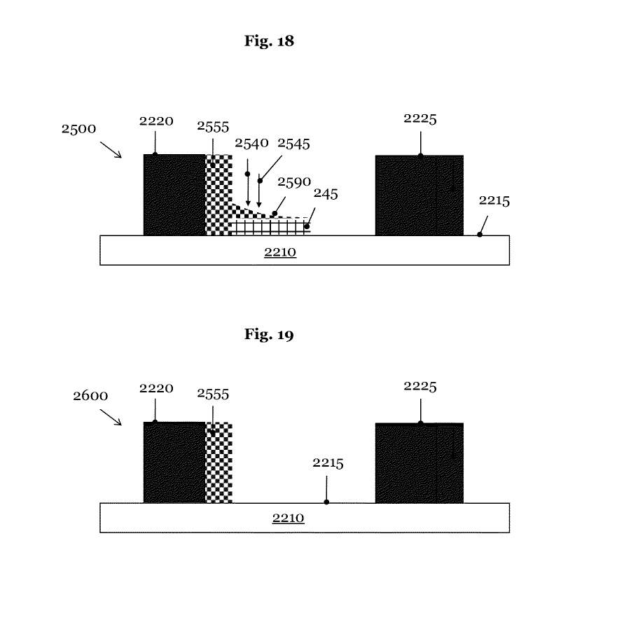

FIG. 19 schematically represents the deposited absorber layer 2555 and the thin absorber layer 2590 on the protection layer 2450 after finalization of the deposition process for repairing the defect 2230. In the last process step, the protection layer 2450 is again removed from the surface 2215 of the substrate 2210 in an etching process 2500. As already explained in the context of FIG. 13, the etching process takes place with an electron beam induced etching process whose parameters are explained above in the context of the discussion of FIG. 13. In the etching process 2500 of FIG. 18, nitrosyl chlorine (NOCl) is used as etching gas 2545 similar to the etching process of FIG. 13.

The protection layer 2350 of FIG. 18 can residue-free be removed from the substrate 2210 of the mask 2250 using usual cleaning processes, in an analog manner to the protection layer 1150 of FIG. 5.

Finally, FIG. 19 shows the segment of the mask 2200 after finalization of the removal of the protection layer 2350. The discussed correction process has essentially removed the defect 2030 of lacking MoSi material without damaging the surface 2215 of the substrate 2210 of the mask 2200.

1. A method for protecting a substrate during a processing by at least one particle beam, the method comprising the following steps:
a. applying a locally limited protection layer on the substrate;
b. etching the substrate and/or a layer arranged on the substrate by the at least one particle beam and at least one gas; and/or
c. depositing material onto the substrate by use of the at least one particle beam and at least one precursor gas; and
d. removing the locally limited protection layer from the substrate.

2. The method according to claim 1, wherein applying the locally limited protection layer comprises applying the protection layer adjacent to a portion of the substrate or to the layer to be processed and/or applying the protection layer in a distance from the layer within which material is to be deposited onto the substrate.

3. The method according to claim 1, wherein applying the protection layer comprises depositing a protection layer which has an etch selectivity compared to the substrate of larger than 1:1.

4. The method according to claim 1, wherein applying the protection layer comprises depositing at least one metal containing layer by use of an electron beam and at least one volatile metal compound on the substrate.

5. The method according to claim 4, wherein the at least one volatile metal compound comprises at least one metal carbonyl precursor gas, and wherein the at least one metal carbonyl precursor gas comprises at least one of the following compounds: molybdenum hexacarbonyl (Mo(CO)₆), chromium hexacarbonyl (Cr(CO)₆), vanadium hexacarbonyl (V(CO)₆), tungsten hexacarbonyl (W(CO)₆), nickel tetracarbonyl (Ni(CO)₄), iron pentacarbonyl (Fe₃(CO)₅), ruthenium pentacarbonyl (Ru(CO)₅), or osmium pentacarbonyl (Os(CO)₅).

6. The method according to claim 4, wherein the at least one volatile metal compound comprises a metal fluoride, and wherein the metal fluoride comprises at least one of the following compounds: tungsten hexafluoride (WF₆), molybdenum hexafluoride (MoF₆), vanadium fluoride (VF₂, VF₃, VF₄, VF₅), and/or chromium fluoride (CrF₂, CrF₃, CrF₄, CrF₅).

7. The method according to claim 1, wherein the locally limited protection layer has a thickness of 0.2 nm-1000 nm.

8. The method according to claim 1, wherein depositing material on the substrate comprises depositing material on the substrate adjacent to the layer arranged on the substrate.

9. The method according to claim 1, wherein the at least one gas comprises at least one etching gas.

10. The method according to claim 9, wherein the at least one etching gas comprises: xenon difluoride (XeF₂), sulfur hexafluoride (SF₆), sulfur tetrafluoride (SF₄), nitrogen trifluoride (NF₃), phosphor trifluoride (PF₃), tungsten hexafluoride (WF₆), molybdenum hexafluoride (MoF₆), fluorine hydrogen (HF), nitrogen oxygen fluoride (NOF), triphosphor trinitrogen hexafluoride (P₃N₃F₆) or a combination of these gases.

11. The method according to claim 1, wherein removing the protection layer comprises directing the electron beam and at least one second etching gas onto the protection layer, wherein the at least one second etching gas comprises an etch selectivity compared to the substrate of larger than 2:1.

12. The method according to claim 1, wherein removing the protection layer comprises directing the electron beam and at least one second etching gas onto the protection layer, wherein the at least one second etching gas comprises a chlorine containing gas, a bromine containing gas, an iodine containing gas and/or a gas which comprises a combination of these halogens.

13. The method according to claim 12, wherein the at least one second etching gas comprises at least one chlorine containing gas.

14. The method according to claim 1, wherein removing the protection layer from the substrate takes place by using a wet chemical cleaning of the substrate.

15. The method according to claim 1, wherein the substrate comprises a substrate of a photolithographic mask and/or the layer arranged on the substrate comprises an absorber layer.

16. The method according to claim 15, wherein the absorber layer comprises MoₓSiO_{y}N_{z}, wherein 0≦x≦0.5, 0≦y≦2, and 0≦z≦4/3.

17. A method for removing portions of an absorber layer which is arranged on portions of a surface of a substrate of a photolithographic mask, wherein the absorber layer comprises MoₓSiO_{y}N_{z}, and wherein 0≦x≦0.5, 0≦y≦2, and 0≦z≦4/3, the method comprising the step:
directing at least one particle beam and at least one gas on at least one portion of the absorber layer to be removed, wherein the at least one gas comprises at least one etching gas and at least one second gas, and wherein the at least one gas comprises an etching gas and at least one second gas in one compound.

18. The method according to claim 17, further comprising the step: changing a ratio of gas flow rates of the at least one etching gas and the at least one second gas during a time period the at least one particle beam is directed on the at least one portion of the absorber layer to be removed.

19. The method according to claim 17, further comprising the step: changing the composition of the at least one second gas prior to reaching a layer boundary between the absorber layer and the substrate.

20. The method according to claim 17, wherein the at least one second gas comprises an ammonia providing gas.

21. The method according to claim 20, wherein the at least one ammonia providing gas comprises ammonia (NH₃), ammonium hydroxide (NH₄OH), ammonium carbonate (NH₄)₂CO₃), diimine (N₂H₂), hydrazine (N₂H₄), hydrogen nitrate (HNO₃), ammonium hydrocarbonate (NH₄HCO₃), and/or diammonium carbonate ((NH₃)₂CO₃).

22. The method according to claim 20, wherein the at least one etching gas and the at least one ammonia providing gas are provided in a compound, and wherein the compound comprises trifluoro acetamide (CF₂CONH₂), triethylamine trihydrofluoride ((C₂H₅)₃N.₃HF), ammonium fluoride (NH₄F), ammonium difluoride (NH₄F₂) and/or tetraammine copper sulfate (CuSO₄.(NH₃)₄).

23. The method according to claim 17, wherein the at least one second gas comprises at least water vapor.

24. The method according to claim 23, wherein the at least one second gas comprises at least one ammonia providing gas and water vapor.

25. The method according to claim 17, wherein the at least one second gas comprises a metal precursor gas, and wherein the at least one metal precursor gas comprises at least one of the following compounds: molybdenum hexacarbonyl (Mo(CO)₆), chromium hexacarbonyl (Cr(CO)₆), vanadium hexacarbonyl (V(CO)₆), tungsten hexacarbonyl (W(CO)₆), nickel tetracarbonyl (Ni(CO)₄), iron pentacarbonyl (Fe₃(CO)₅), ruthenium pentacarbonyl (Ru(CO)₅) and osmium pentacarbonyl (Os(CO)₅).

26. The method according to claim 25, wherein the at least one second gas comprises a metal carbonyl and water and/or at least one ammonia providing gas.

27. The method according to claim 17, wherein the at least one second gas comprises oxygen, nitrogen and/or at least one nitrogen oxygen compound.

28. The method according to claim 27, wherein the at least one second gas comprises oxygen, nitrogen and/or at least one nitrogen oxygen compound, and an ammonia providing gas.

29. The method according to claim 27, wherein the at least one second gas comprises oxygen, nitrogen and/or at least one nitrogen oxygen compound, and water vapor.

30. The method according to claim 27, wherein directing the at least one second gas onto a portion of the absorber layer to be removed comprises activating the oxygen, the nitrogen and/or the at least one nitrogen oxygen compound by means of an activation source.

31. The method according to claim 1, further comprising executing at least one of the steps of the claim 17.

32. The method according to claim 1, wherein the substrate of the photolithographic mask comprises a material which is transparent in the ultraviolet wavelength range, and/or wherein the particle beam comprises an electron beam.

33. An apparatus for protecting a substrate during a processing by means of at least one particle beam comprising:
a. means for arranging a locally limited protection layer on the substrate;
b. means for etching the substrate and/or a layer arranged on the substrate by use of the at least one particle beam and at least one gas; and/or
c. means for depositing material on the substrate by means of the at least one particle beam and at least one precursor gas; and
d. means for removing the locally limited protection layer from the substrate.

34. The apparatus according to claim 33, wherein the apparatus is further configured to execute a method according to claim 1.

35. The method according to claim 33, further comprising means for generating a second particle beam for activating oxygen, nitrogen and/or a nitrogen oxygen compound.
